(19) United States
(12) Patent Application Publication
(10) Pub. No.: US 2014/0067185 A1
(43) Pub. Date: Mar. 6, 2014

(54) IN-SITU ROBOTIC INSPECTION OF COMPONENTS

(71) Applicants: Nilesh Tralshawala, Rexford, NY (US); Bryon Edward Knight, Ballston Lake, NY (US); Harry Israel Ringermacher, Delanson, NY (US)

(72) Inventors: Nilesh Tralshawala, Rexford, NY (US); Bryon Edward Knight, Ballston Lake, NY (US); Harry Israel Ringermacher, Delanson, NY (US)

(73) Assignee: GENERAL ELECTRIC COMPANY, Schenectady, NY (US)

(21) Appl. No.: 13/603,599

(22) Filed: Sep. 5, 2012

(51) Int. Cl. G05D 1/02; G01N 23/02; G01R 33/12; G01N 29/04; H01L 27/146

(52) U.S. Cl. 701/24; 73/596; 250/208.1; 250/349; 324/239; 378/58

(57) ABSTRACT

Methods and systems for inspecting a component within an assembled turbomachine are disclosed. At least one miniature robotic device having a non-destructive testing structure attached thereto is configured to travel around a surface of the component. The non-destructive testing structure gathers data related to the surface, and sends the data to a computing device connected to the at least one miniature robotic device. In one embodiment, the non-destructive testing structure comprises an image capture device and an infrared (IR) heat source.

### FIELD OF THE INVENTION

The subject matter disclosed herein relates to turbines. More particularly, aspects of the disclosure relate to systems for in-situ inspection of components in a turbine using robotic infrared (IR) thermography and/or other miniaturized inspection methods.

### BACKGROUND OF THE INVENTION

During operation of a turbomachine (e.g., a gas turbine), components within that turbine (e.g., rotor and stator blades) are exposed to high pressures and temperatures, which can cause the protective thermal coatings to degrade and spall and cracks to form in the components. Early detection of crack formation and coating health are desirable so that suitable measures can be initiated to fix or replace components, before serious consequences occur.

Visual inspections of components can be done, but visual inspection is unreliable, and cannot detect cracks that have no surface opening (i.e., closed cracks) or delaminations of the coatings. Even when a visible crack with a surface opening (i.e., an open crack) is detected, it is not possible to quantify depth of the crack using visual inspection. In addition, unless there is an obvious spallation of the coatings their health is difficult to judge. Conventionally, a complimentary modality, such as ultrasonic testing (UT) or eddy current (EC) or x-ray or gamma-ray radiographic imaging needs to be used to obtain this quantification (e.g., length, depth, etc.) and also to detect closed cracks that could be missed using a visual only approach. UT and EC modalities require a coupling medium or equi-pressure surface contact, respectively, which is not necessary for visual/optical, IR or radiographic inspections.

### BRIEF DESCRIPTION OF THE INVENTION

Systems for inspecting components in-situ within an assembled turbomachine are disclosed. At least one miniature robotic device is used to travel around a surface of a component to be inspected. The robotic device includes a non-destructive testing structure mounted thereon, configured to gather data related to the surface under the miniature robotic device. In one embodiment, the non-destructive testing structure uses infrared (IR) thermography, e.g., an IR heat source, to direct heat towards the surface to be inspected, and an image capture device to take thermal images of the surface. Data from the non-destructive testing structure can then be analyzed by a computing device to identify and quantify cracks and/or defects in the component being inspected.

A first aspect of the invention includes a system for inspecting a component in-situ within an assembled turbomachine, the system comprising: at least one miniature robotic device configured to travel around a surface of the component, the at least one robotic device having a non-destructive testing structure attached thereto configured to gather data related to the surface; and at least one computing device connected to the at least one miniature robotic device, the at least one computing device configured to receive data from the at least one miniature robotic device relating to the surface of the component.

A second aspect of the invention includes a method of inspecting components in-situ within an assembled turbomachine, the method comprising: providing a plurality of miniature robotic devices, each robotic device having a non-destructive testing structure attached thereto; simultaneously moving the plurality of miniature robotic devices around a surface of a component; and receiving data from at least one non-destructive testing structure.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a perspective view of a system according to an embodiment of the invention being utilized in connection with a blade in a turbomachine;

FIG. 2 shows a schematic of one miniature robotic device including a non-destructive testing device according to an embodiment of the invention;

FIG. 3 shows a schematic of a system according to an embodiment of the invention;

FIG. 4 shows a schematic of a system according to another embodiment of the invention; and

FIG. 5 shows a flow chart showing a method for inspecting components according to an embodiment of the invention.

It is noted that the drawings of the invention are not necessarily to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

Systems for inspecting surfaces of components in-situ within a turbomachine, e.g., blades or vanes, are disclosed. As discussed in more detail herein, in one embodiment, structured infrared (IR) light is created, e.g., multiple lines using programmable light emitting diodes (LEDs), and a cooled IR focal plane detector chip can then image surface temperature as a function of time. Multiple robots with LED driven sources and IR detectors can be spread out over the surface area of interest, enabling full coverage. The thermal images can be converted into time-of-flight maps and temperature maps at a specific critical time, synchronized with IR LEDs on-off triggers. These images can give a direct indication of a defect size. Comparison can then be carried out with optical images. The resulting fused images directly supply quantitative defect information.

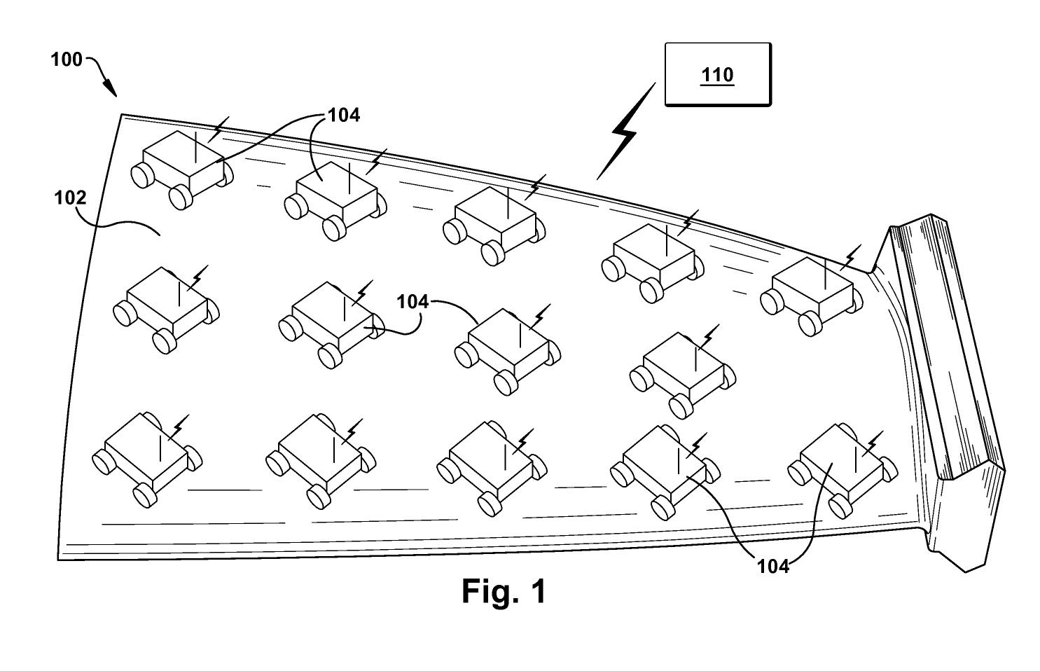

Turning to FIG. 1, one embodiment of the invention is shown. System 100 is shown in use inspecting a blade 102. As known in the art, a blade 102 is within a turbomachine (not shown) and once assembled within the turbomachine, is inaccessible for visual inspection or inspection by conventional large testing equipment.

As shown in FIG. 1, system 100 includes at least one miniature robotic device 104 configured to travel around a surface of blade 102 in an assembled turbomachine. It is understood that miniature robotic device 104 can comprise any known robotic device capable of being directed across a surface, for example, a robot, a crawler, a snake, a flying mote etc.

Each miniature robotic device 104 includes a non-destructive testing structure attached thereto. In one embodiment, the non-destructive testing structure can use infrared (IR) thermography to gather data related to the surface of blade 102 under device 104. However, as discussed herein, other non-destructive testing structures can be used, for example, optical imaging, ultrasonic testing (UT), x-ray or gamma-ray radiography or eddy current (EC).

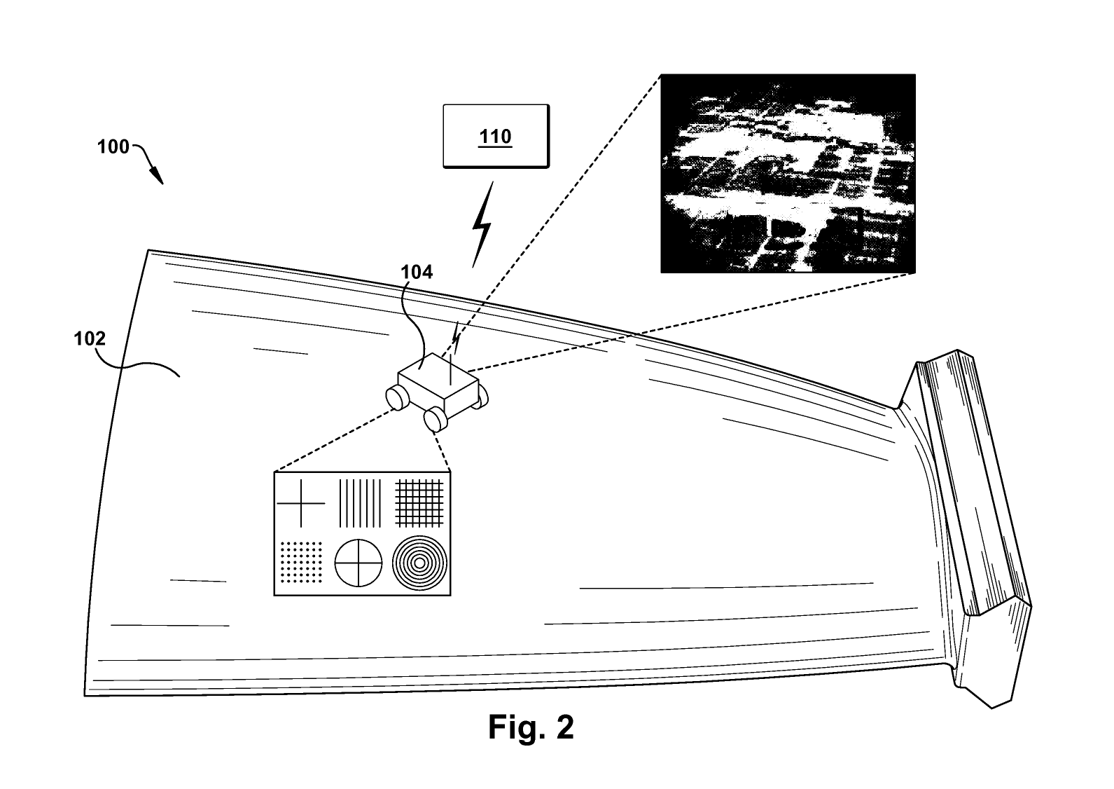

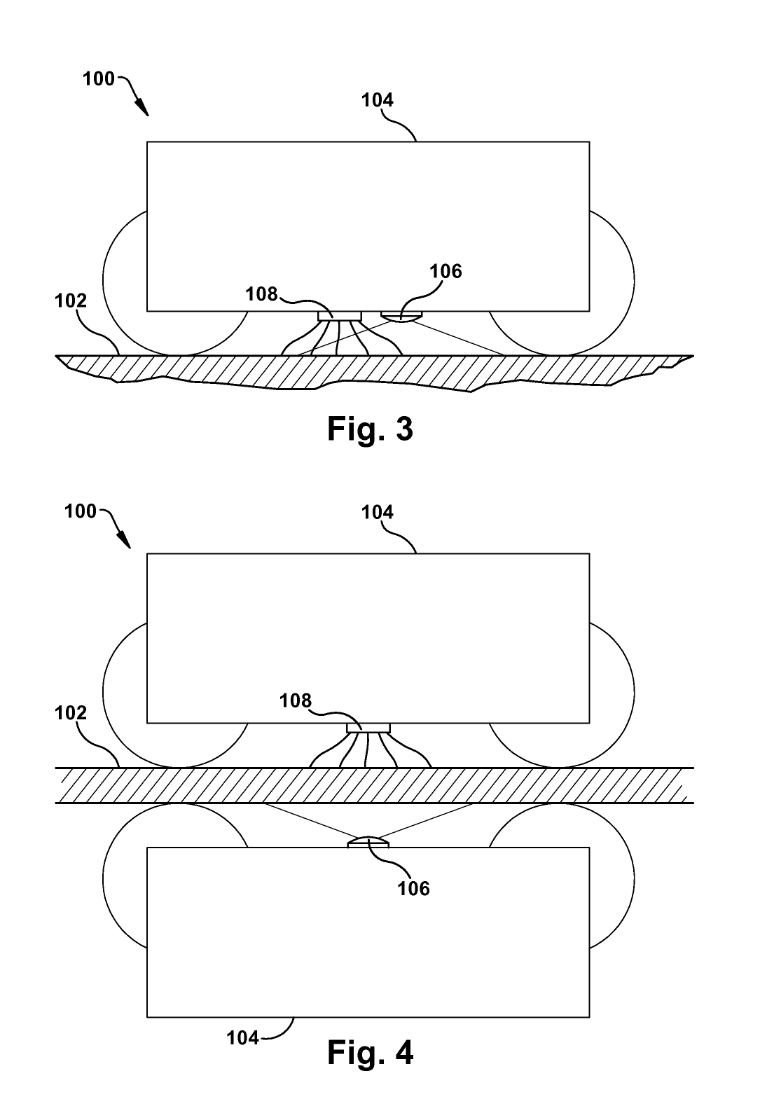

In one embodiment, as shown in more detail in FIG. 2, IR thermography is used, with robotic device 104 including an image capture device 106 and an IR heat source 108. IR heat source 108 directs a structured IR light down onto the surface of blade 102, using an array of programmable light emitting diodes (LEDs). Any pattern of structured light can be used, examples of which can be seen in FIG. 3, depending on the location of cracks being detected and the type of component being inspected., e.g., with or without a coating. Therefore, IR source 108 produces a structured pattern of heat on the surface of component 102 being inspected.

Image capture device 106 is configured to take thermal images of the surface of blade 102, for example, of the surface under, or proximate to, robotic device 104. A plurality of thermal images can be taken, each showing a temperature of blade 102. As shown in FIG. 3, in one embodiment, image capture device 106 and IR heat source 108 are directed at a surface directly under robotic device 104. However, it is understood that image capture device 106 and IR heat source 108 can be directed to any area proximate to robotic device 104. For example, an area in front of, behind, or to the side of robotic device 104.

It is also possible that through-component heat flow can be measured by positioning IR heat source 108 and image capture device 106 on two different robots on the opposite surfaces of 102, as shown in FIG. 4. In this embodiment, the source and imaging devices are on the opposite sides of the component being inspected. Moving IR heat source 108 and image capture device 106 independently and/or in-collaboration with each other, additional complementary information can be obtained for flaw/defect characterization. This can be time advantageous for determination of deep material flaws, and is especially useful in IR thermography, UT or x-ray/gamma-ray radiography.

As shown in FIG. 1, a plurality of robotic devices 104 can be used, each with its own attached non-destructive testing structure. Devices 104 can be spread out over the surface area of blade 102, and devices 104 can be programmed to simultaneously move around the surface of blade 102, enabling full coverage of the surface to be inspected, e.g., blade 102. Each robotic device 104 can have the same or a different type of non-destructive testing structure attached thereto. For example, robotic devices 104 can each have a testing structure that uses a different modality (e.g., EC, UT, IR, x-ray or gamma-ray). In this way, multiple robotic devices 104 can be used to allow simultaneous multi-modal inspections. Complementary information from each type of non-destructive testing device can be gathered for full characterization of flaws. This additional information can better inform a user as to whether repairs are needed, and if yes, if they can be done in-situ or require disassembly, or whether components need to be replaced or scrapped.

In another embodiment, shown in FIG. 3, one robotic device 104 can be used, and moved across an entire surface to be inspected. Device(s) 104 can be moved in any desired pattern, ensuring coverage of the entire surface to be inspected. If a plurality of devices 104 are used, each device can be moved in an independent pattern, or the entire array of devices 104 can be moved in a similar pattern.

Each non-destructive testing structure on each robotic device 104 is connected to at least one computing device 110. The connection to computing device 110 can be wired or wireless, as known in the art. In one embodiment, robotic device 104 includes an antenna configured to receive and send signals to/from computing device 110. Such signals can comprise instructions to the robotic device instructing it how to move across the surface, and/or instructions to image capture device 106 or IR heat source 108. In addition to receiving signals, robotic device 104 and/or the components attached thereto, can send signals to computing device 110. For example, sending data related to the surface being inspected, e.g., images from image capture device 106.

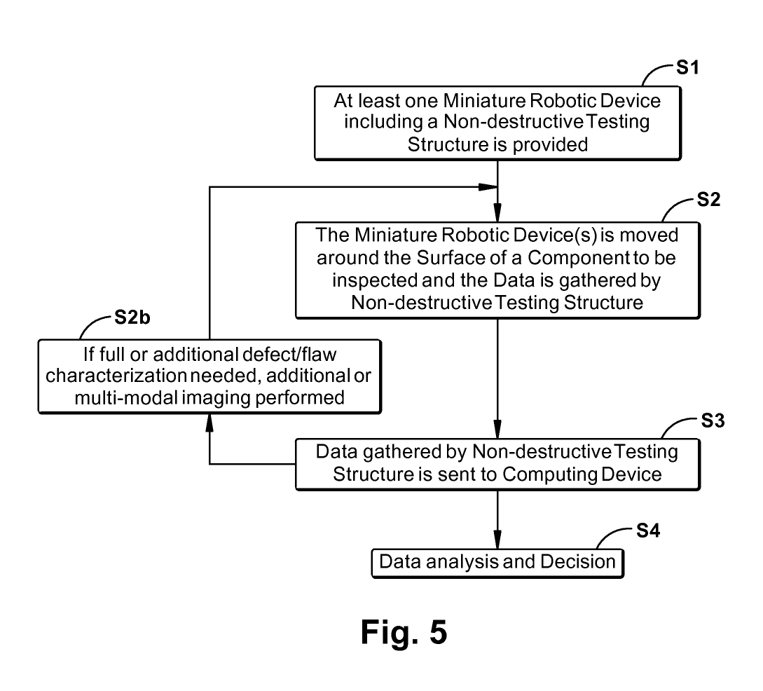

A method using system 100 to inspect a component in a turbomachine is shown in FIG. 5. In step S1, a plurality of miniature robotic devices 104 are provided, each robotic device 102 having a non-destructive testing structure attached thereto. As discussed herein, in one embodiment, the non-destructive testing structure can comprise IR thermography, i.e., a thermal image capture device 106 and an IR heat source 108. In step S2, the plurality of miniature robotic devices are moved around a surface of a component, e.g., blade 102, to obtain a full surface image, or a partial surface image, as desired. As the robotic devices are moved, IR heat source 108, powered by an LED on-off trigger, produces localized heat at the area of blade 102 under robotic device 102. In addition, image capture device 106 takes periodic thermal images of that same area under robotic device 102. In step S3, data, e.g., the thermal images, is sent to computing device 110. In iterative step S2b, multimodal imaging can be utilized, i.e., robotic devices with other modalities are employed if necessary to fully characterize the flaws, if any, on component 102. In step S4, fully characterized flaws are analyzed and a decision is made as to whether the component needs to be scrapped/replaced, if an in-situ repair can be carried out, or if a disassembly would be required for repairs.

Computing device 110 can analyze the thermal images, for example, converting the images into time-of-flight maps and temperature maps at specific times, synchronized with the IR LEDs on-off triggers. These thermal images can give a direct indication of defect size. Computing device 110 can then compare the thermal images with optical images (e.g., taken with another image capture device similar to image capture device 106, but sensitive to visible light as opposed to IR; or previously obtained). The resulting fused images directly supply quantitative defect information.

Embodiments of the invention allow IR thermography to be used in small or hard to access spaces. The robotic devices allow testing structures to reach areas of a turbomachine that are typically only reachable when the turbomachine is disassembled. For example, multiple robots can be programmed to enter a structure of interest, and inspections can be performed in-situ, without disassembling the structure, e.g., a gas turbine. While embodiments of this invention have been discussed in connection with blades in a turbomachine, it is understood that any conventionally hard to reach surface can be inspected using embodiments of this invention, for example, vanes, blades, buckets, and/or nozzles in a turbomachine.

Embodiments of this invention use IR thermography to detect and quantify defects in a surface to be inspected. IR heat source 108 produces heat in various patterns shown in FIG. 1, and as that heat travels through the surface of blade 102, it will move in predicable ways. For example, when heat encounters a crack, the heat flow will go around the crack. A thermal image of the surface is taken using image capture device 106. These thermal images can be used to see how the heat moves across the surface. The relative temperatures of different points on the surface can indicate where a crack is, and a depth of such a crack. Even cracks that are “closed” or micro-cracks, can be detected as even closed or tiny cracks will cause a change in the heat flow across the surface and, will manifest themselves as changes in effective thermal diffusivity of that region with micro-cracks that will be different from the host surface 102. Use of robotic device(s) 104 allow simultaneous mapping of heat flow anomalies across an entire surface to be inspected. On the other hand, uniform illumination of the surface 102, would allow measurement of coating properties, e.g., thicknesses and delaminations.

In either case, the LED heat source of this invention moves over the full surface to be inspected, e.g., by using an array of co-robots 104 that allow synchronized measurements over the whole surface. Whereas the conventional IR thermography requires large space and high intensity lamps, the embodiments of this invention allow IR thermography to be used in closed spaces (e.g. inside gas turbine—in small spaces between blades and airfoils) and since local heating is delivered, small LED sources are sufficient. Embodiments of this invention are LED based, near field method, thus allowing smaller power and exact electronic control of LED on-off and emitted pattern control.

In another embodiment of the invention, the array of miniature robotic devices 102 can also be used to monitor or inspect for additional things, other than cracks. For example, parts in a turbomachine can include a protective coating, which, over time, can lift or peel. The array of miniature robotic devices 102 can be used to determine the state of that protective coating, i.e., determining whether it is cracking, peeling, lifting, etc.

Any modality can be used with this array of miniature robotic devices 104, for example, IR thermography, optical imaging, EC, or UT, or X-ray or Gamma-ray radiography. As discussed herein, in other embodiments, other non-destructive testing structures can be used in conjunction with miniature robotic devices 104. For example, an optical image can be obtained using image capture device 106 connected to robotic device 104. Such optical images taken of the surface directly below, or proximate to, device 104 would be desirable as image capture device 106 would be substantially perpendicular to the surface, in other words, a direct view of the surface could be obtained. In contrast, when conventional image capture devices, such as borescopes, are used, a skewed perspective angle results in incomplete coverage or angled views of the surface. In other embodiments, the non-destructive testing device comprises devices such as small ultrasonic transducers for ultrasonic testing (UT) or flexible, micropatterned eddy current arrays called ECAPs (Eddy Current Array Probes). In addition, very small size x-ray and gamma-ray sources such as Irridium-192, Caesium-132 or Cobolt-60 are now available that would enable robot-deployed radiography. Using miniature robotic devices 104 with UT or EC imaging allows a constant surface pressure to be applied despite complex curved surfaces. All these modalities can be deployed in single-sided or -front-front mode (FIG. 3) or two-sided or front-back mode (FIG. 4) to enable reflection and transmission measurements, respectively.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. It is further understood that the terms “front” and “back” are not intended to be limiting and are intended to be interchangeable where appropriate.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

We claim:

1. A system for inspecting a component within an assembled turbomachine, the system comprising:
at least one miniature robotic device configured to travel around a surface of the component, the at least one robotic device having a non-destructive testing structure attached thereto configured to gather data related to the surface; and
at least one computing device connected to the at least one miniature robotic device, the at least one computing device configured to receive data from the at least one miniature robotic device relating to the surface of the component.

2. The system of claim 1, wherein the at least one miniature robotic device comprises a plurality of miniature robotic devices configured to simultaneously move around the surface of the component.

3. The system of claim 1, wherein the at least one miniature robotic device comprises one of the following: a robot, a crawler, a snake, and a flying mote.

4. The system of claim 1, wherein the non-destructive testing structure comprises an infrared (IR) heat source and an image capture device.

5. The system of claim 4, wherein the at least one miniature robotic device further includes a light emitting diode (LED) source to produce a localized heat source.

6. The system of claim 4, wherein the IR source comprises a programmable array of light emitting diodes (LEDs).

7. The system of claim 4, wherein the IR source produces a structured pattern of light on the surface of the component.

8. The system of claim 4, wherein the IR source produces a structured pattern of heat on the surface of the component.

9. The system of claim 4, wherein the image capture device is configured to capture thermal images of the surface of the component.

10. The system of claim 1, wherein the non-destructive testing structure comprises an ultrasonic testing (UT) device, a light emitting diode (LED) and image capture device, an eddy current (EC) device, or an x-ray or gamma-ray source and radiographic imaging device.

11. The system of claim 1, wherein the at least one miniature robotic device comprises a plurality of miniature robotic devices, and wherein at least one of the plurality of miniature robotic devices has a non-destructive testing structure attached thereto using a modality of testing different from a modality of testing used by at least one other non-destructive testing structure on at least one other miniature robotic device.

12. A method of inspecting components in-situ within an assembled turbomachine, the method comprising:
providing a plurality of miniature robotic devices, each robotic device having a non-destructive testing structure attached thereto;
moving the plurality of miniature robotic devices simultaneously around a surface of a component; and
receiving data from at least one non-destructive testing structure.

13. The method of claim 9, wherein the non-destructive testing structure comprises an image capture device and an infrared (IR) heat source.

14. The method of claim 13, wherein the plurality of miniature robotic devices each further includes a light emitting diode (LED) source to produce a localized heat source.

15. The method of claim 13, further comprising: using the image capture device, capturing thermal images of the surface of the component.

16. The method of claim 12, wherein the plurality of miniature robotic devices simultaneously move around the surface of the component.

17. The method of claim 12, wherein the miniature robotic devices further include a communications device, and wherein the moving the plurality of miniature robotic devices around the surface of the component includes:
receiving, via the communications device, instructions for a pre-set pattern of movement on the surface of the component.

18. The method of claim 12, wherein the non-destructive testing structure comprises an ultrasonic testing (UT) device, an optical imaging device, a radiographic imaging device, or an eddy current (EC) device.

19. The method of claim 12, wherein at least one of the plurality of miniature robotic devices has a non-destructive testing structure attached thereto using a modality of testing different from a modality of testing used by at least one other non-destructive testing structure on at least one other miniature robotic device.

20. The method of claim 19, wherein the receiving data includes receiving data from non-destructive testing structures using different modalities of testing.
